(19) United States
(12) Patent Application Publication
(10) Pub. No.: US 2014/0349479 A1
(43) Pub. Date: Nov. 27, 2014

(54) METHOD INCLUDING A REMOVAL OF A HARDMASK FROM A SEMICONDUCTOR STRUCTURE AND RINSING THE SEMICONDUCTOR STRUCTURE WITH AN ALKALINE RINSE SOLUTION

(71) Applicant: GLOBALFOUNDRIES Inc., Grand Cayman (KY)

(72) Inventors: Oliver Mieth, Dresden (DE); Torsten Huisinga, Dresden (DE); Carsten Peters, Dresden (DE); Bernd Hintze, Langebrueck (DE); Grit Bonsdorf, Dresden (DE)

(21) Appl. No.: 13/901,778

(22) Filed: May 24, 2013

(51) Int. Cl. H01L 21/768

(52) U.S. Cl. CPC H01L 21/76897
USPC 438/637

(57) ABSTRACT

A method includes providing a semiconductor structure. The semiconductor structure includes an electrically conductive feature including a first metal, a dielectric material provided over the electrically conductive feature and a hardmask. The hardmask includes a hardmask material and is provided over the dielectric material. An opening is provided in the interlayer dielectric and the hardmask. A portion of the electrically conductive feature is exposed at a bottom of the opening. The hardmask is removed. The removal of the hardmask includes exposing the semiconductor structure to an etching solution including hydrogen peroxide and a corrosion inhibitor. After the removal of the hardmask, the semiconductor structure is rinsed. Rinsing the semiconductor structure includes exposing the semiconductor structure to an alkaline rinse solution.

### BACKGROUND OF THE INVENTION

1. Field of the Invention

Generally, the present disclosure relates to the field of integrated circuits, and, in particular, to interconnections in integrated circuits.

2. Description of the Related Art

Integrated circuits typically include a large number of circuit elements, which form an electric circuit. In addition to active devices such as, for example, field effect transistors and/or bipolar transistors, integrated circuits can include passive devices, such as capacitors, inductivities and/or resistors. The devices are connected internally by means of electrically conductive lines including an electrically conductive material such as, for example, copper.

To accommodate all the electrically conductive lines required to connect the circuit elements in modern integrated circuits, the electrically conductive lines may be arranged in a plurality of levels stacked on top of each other. To connect electrically conductive lines provided in different levels, contact vias may be formed in interlayer dielectrics separating the levels from each other. The vias may be filled with an electrically conductive material, which may include a metal such as, for example, copper.

For forming electrically conductive lines and contact vias including an electrically conductive material including copper in a semiconductor structure, the dual damascene technique may be employed.

In the dual damascene technique, contact vias and trenches are formed in an interlayer dielectric. The trenches correspond to the electrically conductive lines. One or more diffusion barrier layers including a diffusion barrier layer material such as, for example, titanium nitride, tantalum and/or tantalum nitride, as well as a layer of the electrically conductive material, for example, a layer of copper and/or a copper alloy, are deposited over the semiconductor structure.

Thereafter, a chemical mechanical polishing (CMP) process may be performed. In the CMP process, portions of the one or more diffusion barrier layers and/or the layer of the electrically conductive material outside the contact vias and trenches may be removed.

Portions of the electrically conductive material in the contact vias and trenches may remain in the semiconductor structure, the trenches filled with the electrically conductive material forming electrically conductive lines that connect circuit elements in the semiconductor structure, the contact vias filled with the electrically conductive material providing electrical connection between different layers, as detailed above. The one or more diffusion barrier layers may substantially prevent or at least reduce a diffusion of the electrically conductive material through the interlayer dielectric, which might adversely affect the functionality of the integrated circuit.

Techniques for forming the contact vias and trenches in the interlayer dielectric include the trench first metal hardmask method. In the trench first metal hardmask method, a layer of the interlayer dielectric may be deposited over the semiconductor structure. Then, a layer of a hardmask material including a metal may be deposited over the interlayer dielectric. The layer of hardmask material may be patterned to form a hardmask having openings that correspond to the trenches to be formed in the interlayer dielectric. Thereafter, a contact via mask, which may, for example, be a photoresist mask, may be formed over the hardmask.

A first etch process adapted to remove the interlayer dielectric may be performed in the presence of the contact via mask. In the first etch process, recesses are formed in the interlayer dielectric at the locations at which the contact vias are to be formed. Thereafter, the contact via mask may be removed, and a second etch process adapted to remove the interlayer dielectric may be performed in the presence of the hardmask. In the second etch process, trenches may be formed in the interlayer dielectric. Moreover, in the second etch process, the depth of the recesses in the interlayer dielectric formed at the location of the contact vias in the first etch process may be increased, wherein contact vias extending through the layer of the interlayer dielectric are formed at the locations of the recesses.

After the second etch process, the hardmask may be removed to prevent a creation of stress in the interlayer dielectric, which might induce the formation of metal opens. The removal of the hardmask may be performed by means of a solvent including hydrogen peroxide. In order to avoid damage of the electrically conductive material exposed at the bottom of the contact vias, a corrosion inhibitor may be employed as part of the clean chemistry. After the removal of the hardmask, a rinse may be performed. In the rinse, the hydrogen peroxide and the corrosion inhibitor are removed.

A problem that may occur in the above-described cleaning process for removing the hardmask is that, during the rinse, the corrosion inhibitor may be removed from the semiconductor structure faster than the hydrogen peroxide, so that the electrically conductive material including copper is exposed to residues of the hydrogen peroxide. This may lead to damage of the electrically conductive material.

The present disclosure provides methods wherein the above-mentioned issue may be avoided or at least reduced.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method disclosed herein includes providing a semiconductor structure. The semiconductor structure includes an electrically conductive feature including a first metal, a dielectric material provided over the electrically conductive feature and a hardmask. The hardmask includes a hardmask material and is provided over the dielectric material. An opening is provided in the dielectric material and the hardmask. A portion of the electrically conductive feature is exposed at the bottom of the opening. The hardmask is removed. The removal of the hardmask includes exposing the semiconductor structure to an etching solution including hydrogen peroxide and a corrosion inhibitor. After the removal of the hardmask, the semiconductor structure is rinsed, wherein the rinsing of the semiconductor structure includes exposing the semiconductor structure to an alkaline rinse solution.

### BRIEF DESCRIPTION OF THE DRAWINGS

The disclosure may be understood by reference to the following description taken in conjunction with the accompanying drawings, in which like reference numerals identify like elements, and in which:

FIGS. 1-7 show schematic cross-sectional views of a semiconductor structure in stages of a method according to an embodiment.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides techniques wherein an alkaline rinse solution is used for rinsing a semiconductor structure after a removal of a metal hardmask by means of an etching solution including hydrogen peroxide. Herein, the terms “alkaline” and “basic” are understood as being synonymous. Moreover, the terms “alkali” and “base” are understood as being synonymous. A relatively quick removal of a corrosion inhibitor such as, for example, pyrazole, from electrically conductive features in a semiconductor structure, for example, from electrically conductive lines in interconnect layers including copper, which may be undesirable, as detailed above, may be caused by the use of a neutral or acidic rinse solution. Providing an alkaline rinse solution instead of a neutral or acidic rinse solution may slow down the removal of the corrosion inhibitor, so that the corrosion inhibitor can remain sufficiently long, and the electrically conductive feature can remain protected by the corrosion inhibitor, until substantially all of the hydrogen peroxide is removed from the semiconductor structure by the rinse solution.

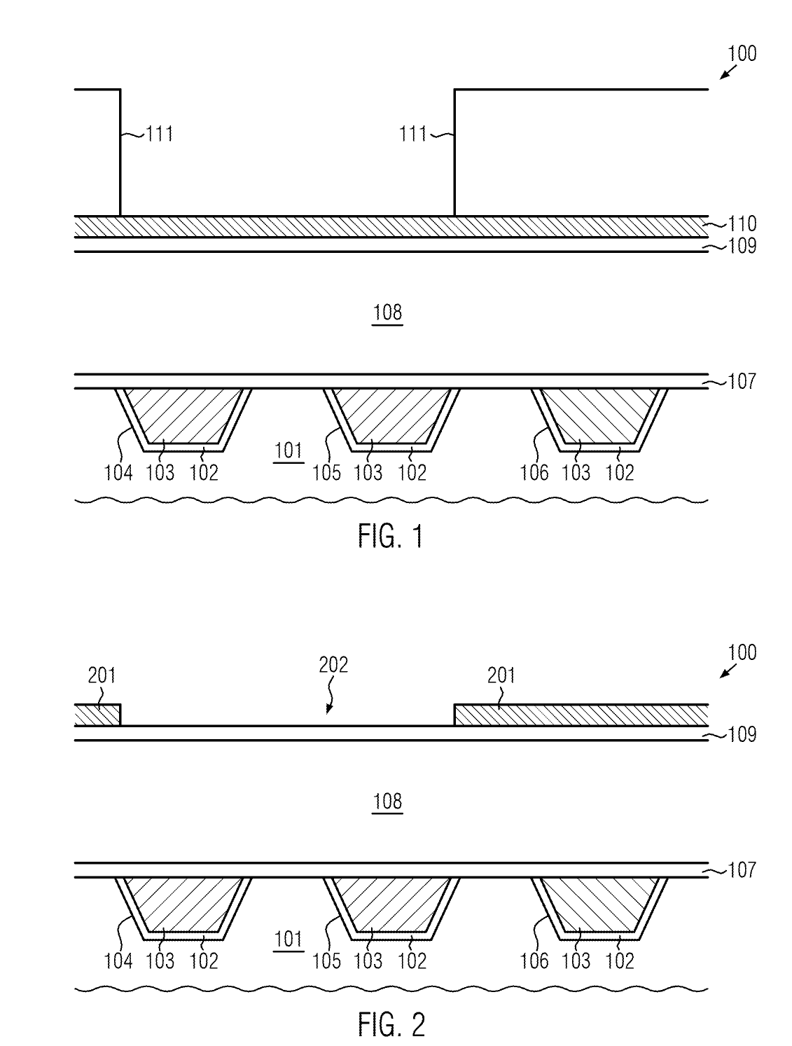

FIG. 1 shows a schematic cross-sectional view of a semiconductor structure 100 in a stage of a manufacturing process according to an embodiment. The semiconductor structure 100 includes a first interlayer dielectric 101. The first interlayer dielectric 101 may be formed above a substrate (not shown). The substrate may be a semiconductor substrate, for example, a bulk semiconductor wafer or die formed of a semiconductor material such as, for example, silicon. Alternatively, the substrate may be a semiconductor-on-insulator (SOI) substrate including a layer of a semiconductor material, for example silicon, formed over a layer of an electrically insulating material such as, for example, silicon dioxide. The layer of electrically insulating material may be provided on a support wafer or die, which may be a silicon wafer or die. In and on the substrate, circuit elements such as, for example, field effect transistors, may be provided.

The first interlayer dielectric 101 may include a low-k dielectric material having a smaller dielectric constant than silicon dioxide, for example a dielectric constant that is smaller than about 4. In some embodiments, the first interlayer dielectric 101 may include an ultra-low-k (ULK) material having a dielectric constant that is smaller than about 3. In some embodiments, the first interlayer dielectric 101 may include one or more materials selected from the group of materials including fluorine-doped silicon dioxide, carbon-doped silicon dioxide, porous silicon dioxide, porous fluorine-doped silicon dioxide, porous carbon-doped silicon dioxide and/or a polymeric dielectric material, for example, a polymeric dielectric material including a polyimide, a polynorbornene, a benzocyclobutene, a polytetraflouro-ethylene, a hydrogen silsesquioxane and/or a methylsilsesquioxane.

The first interlayer dielectric 101 may include one or more electrically conductive features, which may include trenches 104, 105, 106 formed in the first interlayer dielectric 101. The trenches 104, 105, 106 may be filled with a metal 103, for example, copper or a copper alloy. At a bottom surface and at sidewalls of each of the trenches 104, 105, 106, a diffusion barrier layer 102 may be provided between the metal 103 and the first interlayer dielectric 101. The diffusion barrier layer 102 may include one or more layers of a diffusion barrier material such as, for example, tantalum, tantalum nitride, tungsten nitride and/or titanium nitride. The diffusion barrier layer 102 may help to prevent a diffusion of the metal 103 into the first interlayer dielectric 101 and/or a semiconductor material provided below the first interlayer dielectric 101. Additionally, the diffusion barrier layer 102 may help to improve an adhesion between the metal 103 and the first interlayer dielectric 101.

Over the trenches 104, 105, 106 filled with the metal 103 and the first interlayer dielectric 101, an etch stop layer 107 may be provided. In some embodiments, the etch stop layer 107 may include silicon nitride and/or carbon-doped silicon nitride, which may also have diffusion barrier properties for the metal 103.

Over the diffusion barrier layer 107, a second interlayer dielectric 108 may be provided. The second interlayer dielectric 108 may have features corresponding to those of the first interlayer dielectric 101. In particular, the second interlayer dielectric 108 may include a low-k material or an ultra-low-k material. In some embodiments, the second interlayer dielectric 108 and the first interlayer dielectric 101 may be formed of substantially the same material.

Over the second interlayer dielectric 108, a capping layer 109, which may, for example, include silicon dioxide, silicon oxynitride, silicon nitride and/or carbon-doped silicon nitride, and a layer 110 of a hardmask material may be provided. The hardmask material 110 may include a metal that is different from the metal 103 in the trenches 104, 105, 106. In particular, the layer 110 of hardmask material may include a metal other than copper, for example, titanium, tungsten and/or tantalum. The metal in the layer 110 of hardmask material may be provided in compound form, for example, in the form of a nitride of the metal. In some embodiments, the layer 110 of hardmask material may include titanium nitride, tungsten nitride and/or tantalum nitride. FIG. 1 further shows a mask 111 that is provided on the layer 110 of hardmask material. The mask 111 may be a photoresist mask.

The above-described features of the semiconductor structure 100 may be formed as follows. The first interlayer dielectric 101 may be deposited over a semiconductor substrate in and on which circuit elements, such as, for example, field effect transistors, have been formed using techniques of manufacturing circuit elements in integrated circuits. The first interlayer dielectric 101 need not be deposited directly over the semiconductor substrate. In some embodiments, further interlayer dielectrics which may include electrically conductive features such as trenches similar to trenches 104, 105, 106 and contact vias filled with electrically conductive material may be provided between the first interlayer dielectric 101 and the substrate. For depositing the first interlayer dielectric 101, deposition techniques such as chemical vapor deposition (CVD), plasma enhanced chemical vapor deposition (PECVD) and/or spin coating may be employed.

In the first interlayer dielectric 101, the trenches 104, 105, 106 may be formed. Contact vias (not shown) may also be formed. The trenches 104, 105, 106 and the contact vias may be formed means of patterning techniques that may include photolithography and etching. In some embodiments, hardmasks may be employed in the formation of the trenches 104, 105, 106 provided in the first interlayer dielectric 101. In some embodiments, techniques used for forming the trenches 104, 105, 106 and contact vias in the first interlayer dielectric 101 may correspond to techniques for forming trenches and contact vias in the second interlayer dielectric 108 that will be described below.

After the formation of the trenches 104, 105, 106 and contact vias in the first inter-layer dielectric 101, the diffusion barrier layer 102 may be deposited by means of deposition techniques such as CVD, PECVD and/or physical vapor deposition (PVD). Thereafter, the metal 103 may be deposited, for example, by means of electroplating. Then, a planarization process, such as, for example, chemical mechanical polishing, may be performed for removing portions of the diffusion barrier layer 102 and the metal 103 outside the trenches 104, 105, 106 and the contact vias in the first interlayer dielectric 101.

Thereafter, the etch stop layer 107, the second interlayer dielectric 108, the capping layer 109 and the layer 110 of hardmask material may be deposited. Techniques for depositing the second interlayer dielectric 108 may correspond to techniques used for forming the first interlayer dielectric 101 described above. For depositing the etch stop layer 107, the capping layer 109 and the layer 110 of hardmask material, deposition techniques such as CVD, PECVD and/or PVD may be employed.

Thereafter, the mask 111 may be formed, for example, by depositing a photoresist on the semiconductor structure 100 and patterning the photoresist by means of photolithography techniques. The mask 111 may include one or more openings that are provided at locations where one or more trenches are to be formed in the second interlayer dielectric 108. Thus, the openings of the mask 111 correspond to the trenches to be formed in the second interlayer dielectric 108.

FIG. 2 shows a schematic cross-sectional view of the semiconductor structure 100 in a later stage of the manufacturing process. A hardmask 201 may be formed from the layer 110 of hardmask material. For this purpose, the semiconductor structure 100 may be exposed to an etchant adapted to selectively remove the material of the layer 110 of hardmask material relative to the materials of the capping layer 109 and the mask 111. In some embodiments, the etch process may include a reactive ion etch process. In the etch process, portions of the layer 110 of hardmask material that are not covered by the mask 111 may be removed. Portions of the layer 110 of hardmask material that are covered by the mask 111 are protected from an etchant used in the etch process by the mask 111 and remain on the semiconductor structure 100. Thus, the hardmask 201 includes one or more openings 202 corresponding to the trenches to be formed in the second interlayer dielectric 108.

After the formation of the hardmask 201 from the layer 110 of hardmask material, the mask 111 may be removed by means of a resist strip process.

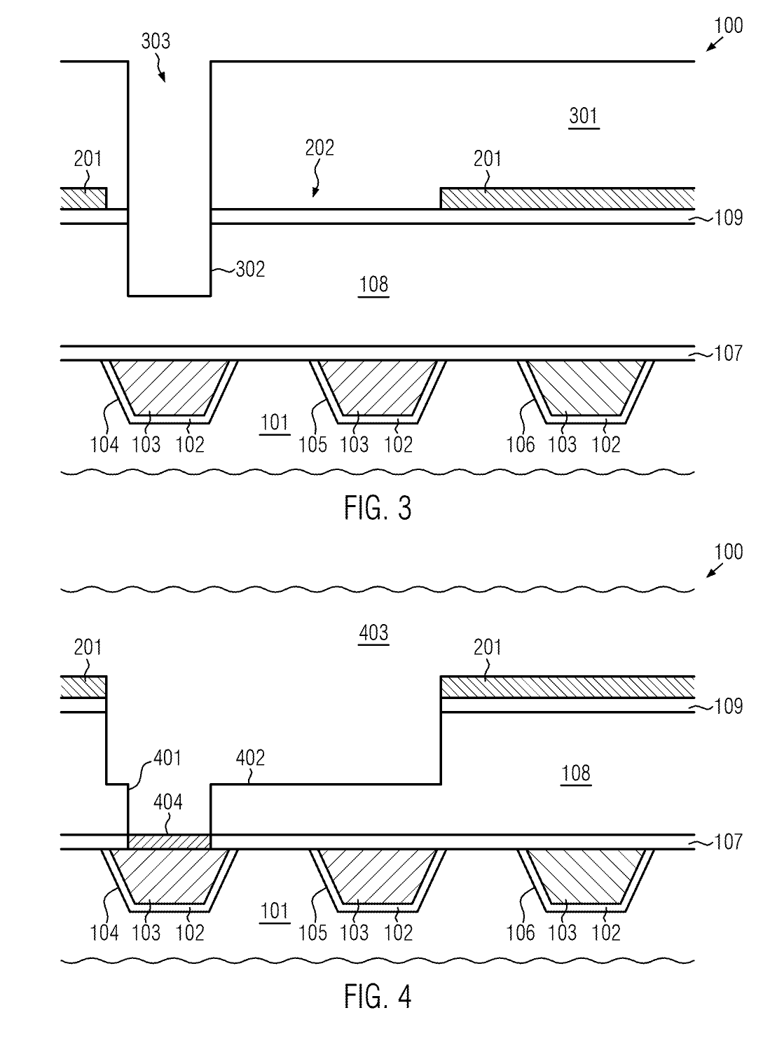

FIG. 3 shows a schematic cross-sectional view of the semiconductor structure 100 in a later stage of the manufacturing process. A contact via mask 301 may be formed over the hardmask 201. The contact via mask 301 may be a photoresist mask and may be formed by means of techniques of photolithography. The contact via mask 301 includes at least one opening 303 that is provided at a location where a contact via (see FIGS. 4-7 wherein an exemplary contact via is denoted by reference numeral 401) is to be formed in the second interlayer dielectric 108. Thus, the at least one opening 303 of the contact via mask 301 corresponds to at least one contact via to be formed in the second interlayer dielectric 108.

As shown in FIG. 3, the opening 303 of the contact via mask 301 may be provided above the trench 104 for forming a contact via providing an electrical connection to the electrically conductive line provided by the trench 104 filled with the metal 103.

After the formation of the contact via mask 301, a first etch process may be performed. The first etch process may be an anisotropic etch process, for example a dry etch process, such as a reactive ion etch process adapted to remove the materials of the capping layer 109 and the second interlayer dielectric 108. In the first etch process, portions of the capping layer 109 and the second interlayer dielectric 108 that are not covered by the contact via mask 301 may be removed. Portions of the capping layer 109 and the second interlayer dielectric 108 below the contact via mask 301 may be protected from being affected by an etchant used in the first etch process by the mask 301, so that they remain in the semiconductor structure 100.

Thus, in the first etch process, a recess 302 is formed. The first etch process may be stopped before the entire second interlayer dielectric 108 below the opening 303 of the contact via mask 301 is removed, so that the etch stop layer 107 is not exposed at the bottom of the recess 302, and a portion of the second interlayer dielectric 108 remains at the bottom of the recess 302. In some embodiments, a depth of the recess 302 may be about one half or more of the thickness of the second interlayer dielectric 108.

FIG. 4 shows a schematic cross-sectional view of the semiconductor structure 100 in a later stage of the manufacturing process. After the first etch process that is performed for forming the recess 302 in the second interlayer dielectric 108, the contact via mask 301 may be removed, for example, by means of a resist strip process.

Thereafter, a second etch process may be performed. The second etch process may be adapted to selectively remove the materials of the capping layer 109 and the second interlayer dielectric 108 relative to the hardmask material of the hardmask 201. Thus, the second etch process may remove portions of the capping layer 109 and the second interlayer dielectric 108 below the opening 202 (see FIG. 3) of the hardmask 201, whereas portions of the capping layer 109 and the second interlayer dielectric 108 below the hardmask 201 are protected from being affected by an etchant used in the second etch process by the hardmask 201 and remain in the semiconductor structure 100.

The second etch process may be an anisotropic etch process, for example, a dry etch process such as a reactive ion etch process. In some embodiments, the second etch process may have features that are substantially identical or at least approximately equal to features of the first etch process employed for forming the recess 302 in the second interlayer dielectric 108.

In the second etch process, portions of the second interlayer dielectric 108 at the bottom of the recess 302 may be removed, so that the etch stop layer 107 is exposed at the bottom of the recess 302. Thus, a contact via 401 extending through the second interlayer dielectric 108 may be formed from the recess 302.

In portions of the semiconductor structure 100 adjacent to the recess 302, which are not covered by the hardmask 201, the capping layer 109 and portions of the second interlayer dielectric 108 may also be removed in the second etch process. However, since adjacent to the recess 302, a greater amount of material of the second interlayer dielectric 108 is present than at the location of the recess 302, portions of the second interlayer dielectric 108 adjacent to the location of the recess 302 and the contact via 401, respectively, may remain in the semiconductor structure 100, so that the etch stop layer 107 is not exposed at these locations. Thus, a trench 402, wherein portions of the second interlayer dielectric 108 are provided at a bottom of the trench 402, may be formed.

Thereafter, a further etch process may be performed for removing the portion of the etch stop layer 107 exposed at the bottom of the contact via, so that the metal 103 in the trench 104 is exposed to the bottom of the contact via 401.

Thereafter, the hardmask 201 may be removed. The removal of the hardmask 201 may include exposing the semiconductor structure 100 to an etching solution 403. For this purpose, the semiconductor structure 100 may be inserted into a bath of the etching solution 403 or the etching solution 403 may be sprayed on the semiconductor structure 100.

The etching solution 403 may include an aqueous solution of hydrogen peroxide (H₂O₂). In some embodiments, the concentration of hydrogen peroxide in the etching solution 403 may be in a range from about 2-20%. In addition to water and hydrogen peroxide, the etching solution 403 may include a corrosion inhibitor. The corrosion inhibitor may include a chemical compound that is suitable for being attached and/or adsorbed to the metal 103 exposed at the bottom of the contact via 401, so that a layer 404 of the corrosion inhibitor is formed.

The layer 404 of corrosion inhibitor may protect the metal 103 from being affected by the etching solution 403. In particular, the layer 404 of corrosion inhibitor may help to substantially avoid or at least reduce a chemical reaction between the hydrogen peroxide in the etching solution 403 and the metal 103.

The corrosion inhibitor may be adapted for being attached and/or adsorbed to the material of the hardmask 201 including a metal that is different from the metal 103 to a less extent than with the metal 103, so that substantially no layer of the corrosion inhibitor protecting the hardmask 201 from chemical reactions with the hydrogen peroxide in the etching solution 403 is formed. Thus, the hydrogen peroxide in the etching solution 403 may react chemically with the material of the hardmask 201 so that the hardmask 201 is removed.

In some embodiments, the corrosion inhibitor may include a chemical compound having a cyclical ring with at least five members. At least two of the members may be nitrogen atoms and the other members may be carbon atoms. Additionally, the corrosion inhibitor may include a functional group adapted to improve an adhesion of the corrosion inhibitor to the copper surface.

In particular, the corrosion inhibitor may include a pyrazole have a cyclical ring with five members, wherein two of the members are nitrogen atoms and the other three members are carbon atoms, wherein the nitrogen atoms are arranged adjacent each other.

In some embodiments, the corrosion inhibitor may include an imidazole including a cyclical ring with five members, two of the members being nitrogen atoms, the other three members being carbon atoms, wherein a carbon atom is located between the nitrogen atoms.

In some embodiments, the corrosion inhibitor may include a triazole including a five-membered ring of two carbon atoms and three nitrogen atoms. In particular, the corrosion inhibitor may include 1, 2, 3-triazole and/or 1, 2, 4-triazole.

In some embodiments, derivatives of pyrazole, imidazole and/or triazole may be employed.

In particular, in some embodiments, the corrosion inhibitor may include a compound selected from the group of compounds including pyrazoles, aminopyrazole derivatives, benzotriazole (BTA), tolyltriazole (TTA), dicyclohexylamine (DDA), carbonic acids, for example, succinic acid, bis-sulfonamidocarboxylic acid and propionic acid and derivatives (esters) of these acids with triethanolamine or glycol, ascorbic acid, citric acid and acetic acid.

The present disclosure is not limited to embodiments wherein the corrosion inhibitor includes a single one of the above-mentioned chemical compounds. In further embodiments, mixtures of pyrazole, imidazole and/or triazole, as well as derivatives thereof, may be used.

Concentrations of the corrosion inhibitor in the etching solution 403 may be in a range from about 0.1-5%.

In some embodiments, the etching solution 403 may be alkaline. For providing an alkaline etching solution 403, the etching solution 403 may include an alkali such as, for example, sodium hydroxide (NaOH), calcium hydroxide (Ca(OH)₂), potassium hydroxide (KOH). In some embodiments, the etching solution 403 may include a buffering agent such as, for example, bipotassium phosphate (K₂HPO₄), disodium phosphate (Na₂HPO₄) and/or monosodium phosphate (NaH₂PO₄).

A pH value of the etching solution 403 may be in a range of about 6.5-8.5. Generally, the pH value of the etching solution 403 may be greater than about 6.

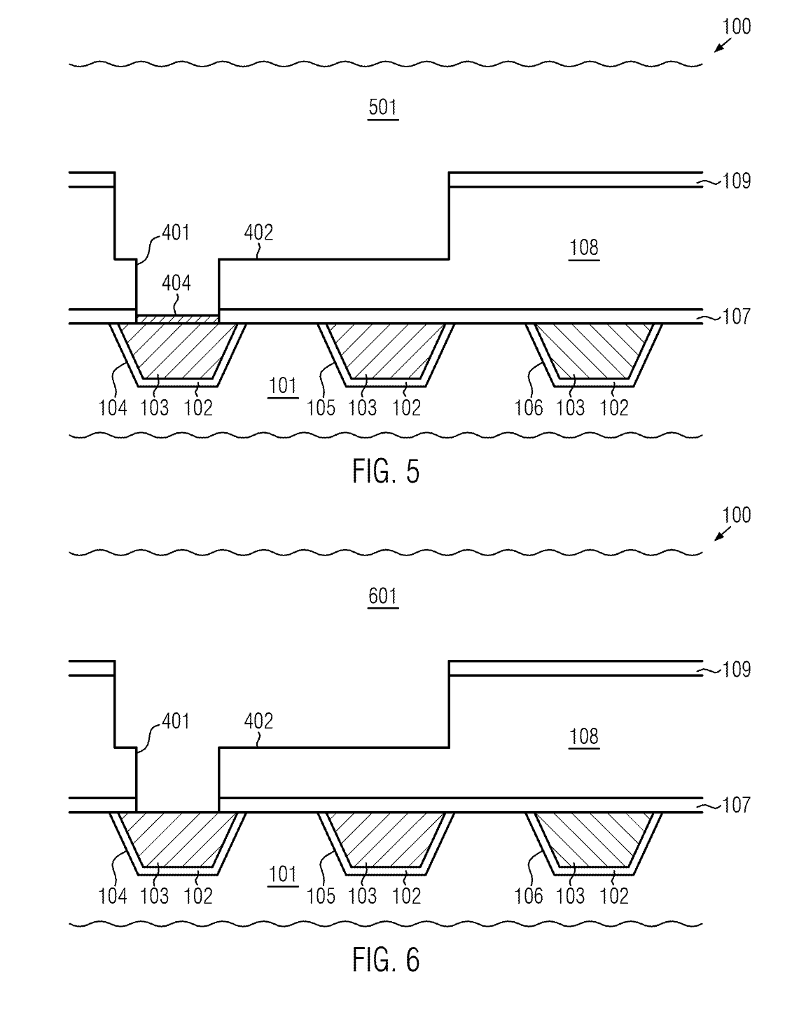

FIG. 5 shows a schematic cross-sectional view of the semiconductor structure 100 in a later stage of the manufacturing process. After the removal of the hardmask 201, the semiconductor structure 100 may be rinsed. For this purpose, the semiconductor structure 100 may be exposed to a rinse solution 501. For this purpose, the semiconductor structure 100 may be inserted into the rinse solution 501, the rinse solution 501 may be sprayed on the semiconductor structure 100 and/or the rinse solution may be flown over the semiconductor structure 100.

The rinse solution 501 may include water. Moreover, the rinse solution 501 may include an alkali, so that the rinse solution 501 is alkaline. The rinse solution may have a pH value of about 7.1 or more, for example, a pH value in a range from about 7.1-8.5. The alkali provided in the rinse solution 501 may include sodium hydroxide (NaOH), calcium hydroxide (Ca(OH)₂), potassium hydroxide (KOH). In some embodiments, the rinse solution 501 may include a buffering agent such as, for example, bipotassium phosphate (K₂HPO₄), disodium phosphate (Na₂HPO₄) and/or monosodium phosphate (NaH₂PO₄). Providing a buffering agent in the rinse solution 501 may help to maintain the pH value of the rinse solution 501 in a desirable range.

In an alkaline environment, the corrosion inhibitor provided in the etching solution 401 may be more strongly attached and/or adsorbed to the metal 103 in the trench 104 that is exposed at the bottom of the contact via 401 than in a neutral or acidic environment. Thus, compared to a rinse of the semiconductor structure 100 with a neutral or acidic rinse solution after exposing the semiconductor structure 100 to the etching solution 403, the layer 404 of the corrosion inhibitor may be maintained for a greater amount of time when the alkaline rinse solution 501 is employed for rinsing the semiconductor 100.

In particular, the layer 404 of the corrosion inhibitor may be maintained on the surface of the metal 103 exposed at the bottom of the contact via 401 at least as long as residues of the hydrogen peroxide from the etching solution 403 are still present at the semiconductor structure 100. Thus, an early destruction of the layer 404 of the corrosion inhibitor, which might entail a chemical reaction between hydrogen peroxide and the metal 103, causing damage of the metal 103, may be substantially avoided or at least reduced.

In some embodiments, both the etching solution 403 and the rinse solution 501 may include an alkali and/or a buffering agent. In some of these embodiments, a concentration of the alkali and/or the buffering agent and/or a pH value of the rinse solution 501 and the etching solution 403 may be approximately equal, wherein, however, different from the etching solution 403, the rinse solution 501 is substantially free of hydrogen peroxide.

FIG. 6 shows a schematic cross-sectional view of the semiconductor structure 100 in a later stage of the manufacturing process. In some embodiments, after rinsing the semiconductor structure 100 with the rinse solution 501, the semiconductor structure 100 may be exposed to water 601. The water 601 may be substantially pure water. For example, the water 601 may be deionized water. For exposing the semiconductor structure 100 to the water 601, the semiconductor structure 100 may be inserted into the water 601, the water 601 may be sprayed on the semiconductor structure 100 and/or the water may be flown over the semiconductor structure 100.

The water 601 may remove residues of the alkali and/or buffering agent in the rinse solution 501, as well as the corrosion inhibitor from the layer 404 of the corrosion inhibitor from the semiconductor structure 100.

In alternative embodiments, exposing the semiconductor structure 100 to the water 601 may be omitted.

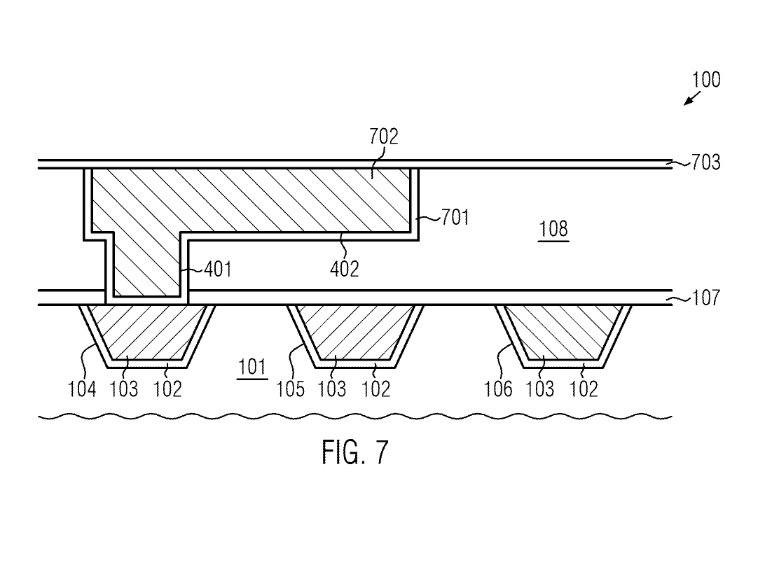

FIG. 7 shows a schematic cross-sectional view of the semiconductor structure 100 in a later stage of the manufacturing process. After exposing the semiconductor structure 100 to the etching solution 403, the rinse solution 501 and/or the water 601, the semiconductor structure 100 may be dried, and a diffusion barrier layer 701 and a metal 702 may be deposited over the semiconductor structure 100. Features of the diffusion barrier layer 701 may correspond to features of the diffusion barrier layer 102, and corresponding methods may be used for its formation. Features of the metal 702 may correspond to features of the metal 103, and corresponding methods may be used for its formation. The metal 702 may fill the contact via 401 and the trench 402, wherein the metal 702 in the trench 402 provides an electrically conductive line in the second interlayer dielectric 108, and the metal in the contact via 401 provides an electrical connection between the electrically conductive line provided by the trench 701 filled with the metal 702 and the electrically conductive line provided by the trench 104 filled with the metal 103.

After depositing the diffusion barrier layer 701 and the metal 702, a CMP process may be performed. In the CMP process, portions of the metal 702 and the diffusion barrier layer 701 outside the trench 402 and the contact via 401 may be removed. Additionally, in the CMP process, the capping layer 109 may be removed completely or partially. Alternatively, the CMP process may be stopped before the capping layer 109 is removed.

Thereafter, an etch stop layer 703 may be deposited over the semiconductor structure 100. Features of the etch stop layer 703 may correspond to features of the etch stop layer 107 described above and corresponding methods may be used for its formation.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
providing a semiconductor structure, the semiconductor structure comprising an electrically conductive feature comprising a first metal, a dielectric material provided over said electrically conductive feature, a hardmask comprising a hardmask material, said hardmask being provided over said dielectric material, and an opening provided in said dielectric material and said hardmask, a portion of said electrically conductive feature being exposed at a bottom of said opening;
removing said hardmask, the removal of said hardmask comprising exposing said semiconductor structure to an etching solution comprising hydrogen peroxide and a corrosion inhibitor; and
after the removal of said hardmask, rinsing said semiconductor structure, wherein rinsing said semiconductor structure comprises exposing said semiconductor structure to an alkaline rinse solution, wherein both said etching solution and said rinse solution comprise the same buffering agent.

2. The method of claim 1, wherein said first metal comprises copper.

3. The method of claim 2, wherein said corrosion inhibitor comprises a chemical compound comprising a cyclical ring comprising at least five members, at least two of the members being nitrogen atoms, the other members being carbon atoms.

4. The method of claim 3, wherein said corrosion inhibitor comprises at least one of a pyrazole, a pyrazole derivative, an imidazole, an imidazole derivative, a triazole, a triazole derivative, a pyrazole derivative, an aminopyrazole derivative, a benzotriazole (BTA), a tolyltriazole (TTA), a dicyclohexylamine (DDA), a carbonic acid, a succinic acid, a bis-sulfonamidocarboxylic acid, a propionic acid, a derivative of any of a succinic acid, a bis-sulfonamidocarboxylic acid and a propionic acid with triethanolamine or glycol, ascorbic acid, citric acid and acetic acid.

5. The method of claim 4, wherein said corrosion inhibitor comprises pyrazole.

6. The method of claim 2, wherein said rinse solution has a pH value of about 7.1 or more.

7. The method of claim 6, wherein said rinse solution has a pH value in a range from about 7.1-8.5.

8. The method of claim 6, wherein said rinse solution is substantially free of hydrogen peroxide.

9. The method of claim 1, further comprising exposing said semiconductor structure to substantially pure water after exposing said semiconductor structure to said alkaline rinse solution.

10. The method of claim 2, wherein said hardmask material comprises a second metal, said second metal being a different metal than said first metal.

11. The method of claim 10, wherein said hardmask comprises said second metal in compound form.

12. The method of claim 11, wherein said hardmask comprises at least one of titanium nitride, tungsten nitride and tantalum nitride.

13. The method of claim 1, wherein said opening comprises a contact via.

14. The method of claim 13, wherein said dielectric material comprises a low-k interlayer dielectric.

15. The method of claim 14, wherein providing said semiconductor structure comprises:
depositing a layer of said dielectric material over said electrically conductive feature;
depositing a layer of said hardmask material over said layer of dielectric material;
forming said hardmask from said layer of hardmask material, the formation of said hardmask comprising forming an opening corresponding to a trench in said layer of hardmask material;
forming a contact via mask over said hardmask, said contact via mask comprising an opening corresponding to said contact via;
performing a first etch process adapted to remove said dielectric material, wherein said contact via mask protects portions of said layer of said dielectric material below the contact via mask from being affected by a first etchant used in said first etch process; and
after the first etch process, removing said contact via mask and performing a second etch process adapted to remove said dielectric material, wherein said hardmask protects portions of said layer of said dielectric material below said hardmask from being affected by a second etchant used in said second etch process.

16. The method claim 15, wherein each of said first and second etch processes comprise a reactive ion etch process.

17. The method of claim 16, wherein said corrosion inhibitor comprises at least one of a pyrazole and a pyrazole derivative, and wherein the method further comprises exposing said semiconductor structure to substantially pure water after exposing said semiconductor structure to said alkaline rinse solution.

18. The method of claim 1, wherein said buffering agent is bipotassium phosphate.

19. The method of claim 1, wherein said buffering agent is disodium phosphate.

20. The method of claim 1, wherein said buffering agent is monosodium phosphate.

21. A method, comprising:
providing a semiconductor structure, said semiconductor structure comprising an electrically conductive feature comprising a first metal, a dielectric material provided over said electrically conductive feature, a hardmask comprising a hardmask material, said hardmask being provided over said dielectric material, and an opening provided in said dielectric material and said hardmask, a portion of said electrically conductive feature being exposed at a bottom of said opening;
removing said hardmask, the removal of said hardmask comprising exposing said semiconductor structure to an etching solution comprising hydrogen peroxide and a corrosion inhibitor; and
after the removal of said hardmask, rinsing said semiconductor structure, wherein rinsing said semiconductor structure comprises exposing said semiconductor structure to an alkaline rinse solution comprising a pH value in a range from approximately 7.1-8.5.
